(19) United States
(12) Patent Application Publication
(10) Pub. No.: US 2006/0286811 A1
(43) Pub. Date: Dec. 21, 2006

(54) Method of optically imaging and inspecting a wafer in the context of edge bead removal

(75) Inventors: Michael Heiden, Woelfersheim (DE); Erwin Thiel, Wilnsdorf (DE); Christof Krampe-Zadler, Castrop-Rauxel (DE)

Correspondence Address: SIMPSON & SIMPSON, PLLC, 5555 MAIN STREET, WILLIAMSVILLE, NY, 14221-5406, US

(73) Assignee: Vistec Semiconductor Systems GmbH, Wetzlar (DE)

(21) Appl. No.: 11/454,740

(22) Filed: Jun. 16, 2006

(30) Foreign Application Priority Data
Jun. 17, 2005 (DE) 10 2005 028 427.2

(51) Int. Cl. H01L 21/469

(52) U.S. Cl. 438/759; 250/458.1

(57) ABSTRACT

The present invention relates to a method of optically imaging a wafer with a photoresist layer, wherein an imaging area on the surface of the wafer is illuminated with light and a fluorescence image is taken in the imaging area based on the fluorescent light irradiated due to the illumination by the excitation light.

### CROSS REFERENCE TO RELATED APPLICATIONS

This patent application claims priority of German Patent Application No. 10 2005 028.427.2, filed on Jun. 17, 2005, which application is incorporated herein by reference.

### FIELD OF THE INVENTION

The present invention relates to a method of inspecting a wafer, in particular for detecting the edge bead removal (EBR) line in the context of edge bead removal. The present invention also relates to a method of edge bead removal that helps with the inspection of the wafer and the detection of the EBR line. Moreover, the present invention relates to a photoresist and an edge bead removal liquid.

In the context of lithography-based semiconductor production processes photoresist is applied to the surface of the wafer in the centrifugal spin coating method. By having the wafer rapidly rotate about its central axis the photoresist is spread on the surface in a thin coating. Due to edge surface effects the photoresist accumulates at the edge of the wafer and forms a bead. It has therefore been found to be necessary to remove the photoresist at the edge of the wafer together with the bead. By means of an edge bead removal liquid, i.e. a solvent, a circular annulus results at the edge of the wafer having a surface free of photoresist.

In the context of quality control in wafer production inspection methods have been developed for detecting the completeness of the photoresist removal and the defined position of the borderline between areas having photoresist and areas having no photoresist, the so-called edge bead removal (EBR) line.

### BACKGROUND OF THE INVENTION

A method of the above type has been disclosed in U.S. 2004/0,223,141 A1. In this method different effects of the polarization of incident light on the blank wafer surface and on the photoresist surface are utilized to detect the EBR line.

### SUMMARY OF THE INVENTION

It is therefore an object of the present invention to complement the state of the art by providing a further method allowing to detect the position of the EBR line on a wafer in a reliable manner. It is another object of the present invention to provide a method of edge bead removal adapted to the inspection method. Moreover it is an object of the present invention to provide a photoresist and an edge bead removal liquid adapted to the present invention.

According to the present invention, the object is achieved in a method of optically imaging a wafer with a photoresist layer by the following method steps:
illuminating an imaging area on the surface of the wafer with light of a wavelength range between 360 nm and 500 nm, wherein the light is polychrome; and,
imaging a fluorescence image of the imaging area from the fluorescent light radiated due to the illumination by the excitation light and wherein the fluorescence image is a color image.

The object is achieved as well by a method of edge bead removal and of inspecting a wafer which comprises the steps of:
partially removing the photoresist from the wafer with a fluorescent EBR liquid, wherein fluorescent EBR liquid diffuses into the EBR line towards the area where the photoresist remains;
illuminating an imaging area on the surface of the wafer with light of a wavelength range between 360 nm and 500 nm, wherein the light is polychrome;
imaging a fluorescence image of the imaging area from the fluorescent light radiated due to the illumination by the excitation light and wherein the fluorescence image is a color image; and,
evaluating the fluorescence image by identifying the fluorescent EBR line.

The light can come from a laser, an LED or from an incoherently illuminating light source, such as an incandescent lamp, a mercury vapor lamp or an arc lamp. The light can be monochrome or polychrome and can have its spectrum limited by means of filters. In the imaging process the wavelength of the incident light can be filtered out by a filter, such as a cut-off filter or a band pass filter. The imaging area can be a single measuring spot on the surface of the wafer or a partial image or the overall image of the surface of the wafer. Individual support positions on the surface of the wafer are also conceivable. In the imaging process, the fluorescent light can be detected by a detector, such as a digital camera, a digital video camera, a linear array camera or a matrix array camera, or even by an SEV.

Suitably it is provided for the wavelength range of the light for imaging to be in the area between 316 nm to 500 nm. In this wavelength range it is possible to induce particularly good fluorescence of common photoresists.

Preferably it is provided for the light of the illumination to be polychrome. This is advantageous in that various layers on the wafer are excited in their specific excitation wavelength to induce fluorescence. The polychrome light can have one or more spectral bands or a plurality of single lines. Ideally the spectral ranges of the illumination are adapted to the excitation wavelengths of the substrates present on the wafer.

Advantageously, the imaged fluorescence image is a color image. Different layers are fluorescent at different wavelengths or are influenced in different ways by their different layer thicknesses or by overlying layers. Using a color image also has the advantage that an increased degree of structural information is imaged on the surface of the wafer.

The fluorescence image is suitably imaged in the dark field of the illumination. This is advantageous in that the much more intensive illumination light does not overlap its intensity with the fluorescent light. A filter can also be positioned in the imaging light path, for example for filtering out any scattered portions of the excited illumination light upstream of the detector.

According to an embodiment of the present invention it is provided that when the fluorescence image is taken, a dark-field image of the imaging area is imaged in addition from the scattered light of the illuminated imaging area. This is advantageous in that structural information can be obtained both from the fluorescent light and from the scattered light. The scattered light can be the scattered light from the illumination used for exciting the fluorescence. However, it is also conceivable to use an additional light source. It must be noted, however, that the wavelength of the fluorescent light should not match the one of the scattered light so that they can be assigned to each detector by means of filters in the imaging beam path, or so that the corresponding images can be distinguished in a single color camera.

According to another embodiment of the invention it is provided that the fluorescent light and the dark field light are imaged simultaneously. This is advantageous in that the inspection process can be carried out within a shorter period of time and that the wafer need not be adjusted again.

According to a preferred embodiment of the invention it is provided that the fluorescent light and the dark field light are coextensive and imaged by the same camera. The dark-field image and the fluorescence image can be generated by the same light source. To achieve this the spectral range of the light source which is also the spectral range of the dark-field image is strongly attenuated with respect to the spectral range of the fluorescent light in the imaging beam path so that the intensity of the dark-field image is about that of the fluorescence image. Suitably the spectral range(s) of the fluorescent light is filtered out of the spectrum of the light source, or a corresponding light source without these spectra is chosen. This is how an overexposure of the fluorescence image caused by the dark-field image or vice versa is avoided.

According to an embodiment it is provided that the fluorescence image is imaged by a color camera and the dark-field image is imaged by a monochromatic camera. This is advantageous in that the two beam paths can be optically filtered independently of each other. In this way a filter can filter out the illumination light upstream of the color camera and a filter can filter out the fluorescent light upstream of the monochromatic camera.

According to a preferred embodiment it is provided that the monochromatic camera has a higher resolution than the color camera. This is advantageous in that the camera is adapted to each type of information. In a fluorescence image usually a color gradient is required rather than detailed structural information. On the other hand, detailed structural information rather than color information is usually a requirement in the dark-field image. This is achieved with the suggested specialization of the cameras.

According to another embodiment of the invention it is provided that the one or two cameras are one or two linear array cameras and that the imaging area has an extension in the form of a line and is moved relative to the wafer surface in a direction perpendicular to its extension during imaging. This is advantageous in that linear scanning of the wafer surface is achieved. As a result of its linear configuration the imaging area is relatively small and only stays in the same place for a short period of time due to the movement. As a result the intensity of the incident illumination light can be chosen to be particularly high so that the fluorescence effect is induced in a particularly efficient way. It is also advantageous in that due to the small width extension of the imaging area there is no problem of depth of focus in oblique imaging.

According to a preferred embodiment of the invention it is provided that the imaging area has a radial orientation to the center of the wafer and that the wafer is rotated about its center axis for movement. The orientation and movement suggested correspond to the specific rotation symmetrical geometry of the wafer. Meandering scanning of the wafer surface with an abrupt reversal of movement is thus avoided and therefore the precision of the measurement is increased.

According to another embodiment it is provided that the imaging area scans a circular annulus delimited by the edge of the wafer on the surface of the wafer. According to a preferred embodiment it is provided that the imaging area covers the EBR line of the wafer. The method described is specially optimized to imaging in the area around the EBR line. The result of the imaging is the image of a circular annulus on the surface of the wafer in the area of the EBR line and the circumferential line of the wafer. The image taken can be shown as a circular annulus or as a straight elongated band with a certain distortion. This enables the image to be readily shown for example on a display screen indicating the angular position and the distance to the center or edge for the structures shown in the image.

It is provided with particular advantage that the fluorescence image is evaluated after imaging whereby the EBR line is identified. The identification of the position of the EBR line in the image and on the wafer is one of the most important and basic bits of information in the area of the wafer edge required for further processing.

Advantageously it is provided that the fluorescence image is evaluated after imaging, with areas being classified in the image. Areas are on the one hand the areas of the wafer where photoresist is present and on the other hand the area of the wafer where the photoresist is removed. Further areas are conceivable such as when there is a stepped edge bead removal line, i.e. when individual layers of the wafer have a differing extension in the direction towards the wafer edge.

Suitably it is provided that after imaging the fluorescence image is evaluated by:
creating a histogram of the image or images;
finding a threshold value from the histogram;
comparing the image with the threshold value; and,
classifying areas in the image based on the comparison.

The method shown for classification has been found to be realizable with particular speed in a data processing system.

It is of particular advantage if the areas of the wafer separated by an EBR line correspond to the classified areas. The two areas are the areas with or without photoresist. The border between the two areas therefore corresponds to the position of the EBR line, which is why the identification of the different areas leads to identifying the position of the EBR line.

According to an embodiment of the invention it is provided that the fluorescent light is compared to the dark-field light. The EBR line is represented as an edge reflection in the dark-field image. The determination of the EBR line in the fluorescence image can be verified by the comparison. The position of the EBR line in the dark-field image can also be identified with the aid of the fluorescence image when the fluorescence image has, for example, a plurality of parallel line structures.

According to the invention the above object is achieved with a photoresist for the manufacture of semiconductor elements on wafers by adding a fluorescent dye to the photoresist. Even though photoresists usually have some fluorescence, there is sometimes only very little of it. By adding more fluorescent dye the presence of photoresist on the wafer and the extension and position of the area of the photoresist on the wafer can be reliably identified with the above described method.

Suitably the use of the above described photoresist, with a fluorescent dye added, is provided for in the above described method.

By using the fluorescent EBR liquid, fluorescent molecules diffuse into the EBR line of the photoresist in the EBR process. This is how the fluorescent ability of the photoresist is established and increased in particular in the area of the EBR line. This is how the EBR line is effectively highlighted in the fluorescence image in the above described method. In this case the photoresist need not have any fluorescent properties. This is why the present method is independent on which photoresist is used.

According to the invention the above object is achieved in an EBR liquid to at least partially remove the photoresist from a wafer by having the EBR liquid consist of a solvent and additional fluorescent dye. The fluorescent dye is here a substance that can be mixed with the solvent and with a greater fluorescence than the solvent. By adding the fluorescent dye the presence of solvent can be detected particularly effectively by means of fluorescence. If the fluorescent dye is fluorescent at another wavelength than that of the photoresist, the border of the photoresist layer can be detected particularly effectively in the EBR line.

Preferably the fluorescent EBR liquid is used for a method implemented as described above.

Of particular advantage is the use of a fluorescent EBR liquid having additional fluorescent dye for one of the above methods. Due to the additional fluorescent dye in the solvent the ability of the EBR liquid to increase the fluorescence in the EBR line is particularly enhanced.

### BRIEF DESCRIPTION OF THE DRAWINGS

The invention will be described in the following in more detail with respect to the schematic representations of an exemplary embodiment. The same reference numerals designate the same elements throughout the individual drawing figures, in which:

FIG. 1 is a side view of an apparatus for the method of the present invention;

FIG. 2 is a top view of an apparatus for the method according to the present invention;

FIG. 3 is a fluorescence image and a dark-field image for the method according to the present invention;

FIG. 4 is a histogram of a fluorescence image for the method according to the present invention; and,

FIG. 5 is a radial sectional side view of the wafer in the area of the wafer edge.

### DETAILED DESCRIPTION OF THE INVENTION

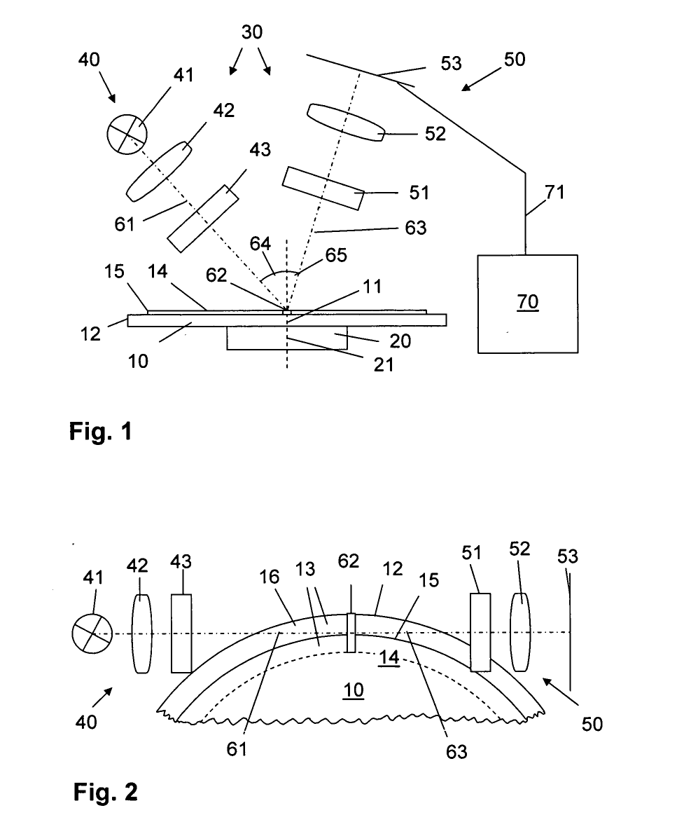

FIG. 1 shows a wafer 10 held by a rotary apparatus 20. The center axis 11 of the wafer is concentric to the rotary axis 21 of the rotary means. A photoresist layer 14 is on the wafer extending up to an EBR line 15 at a distance from wafer edge 12. An imaging means 30 is mounted above the wafer. It consists of illumination means 40 and imaging means 50. Illumination means 40 consists of a light source 41, a beam shaper 42 which could also simply be an objective (lens assembly) and an optical filter 43, all of which in the illumination beam path 61. Illumination beam path 61 of illumination means 40 is incident on the surface of the wafer in an imaging area 62. Imaging area 62 is imaged by imaging means 50 via an optical filter 51 and a lens 52 onto a color CCD linear array camera 53. Herein the incident angle 64 of illumination beam 61 is greater than the angle of reflection 65 of imaging beam 63 of the imaging means. Due to the inequality of the incident angle and the reflection angle a dark-field image is realized. Filter 43 attenuates wavelengths in the range of the expected fluorescence wavelength. Filter 51 attenuates wavelengths outside of the expected fluorescence wavelength. This is how the color CCD linear array camera 53 detects a fluorescence image and a scattered-light image from imaging area 62. The color CCD linear array camera is connected to an image processing means 70 via a data link 71. Image processing means 70 not only receives the camera image of the imaging area but also combines the adjacent imaged imaging areas due to the rotation of rotating means 20 in a combined image.

FIG. 2 shows wafer 10 and the imaging means with illumination means 40 and image detection means 50 in a top view. An edge area 13 is adjacent to wafer edge 12. In edge area 13, EBR line 15 is concentric to wafer edge 12. The photoresist layer extends on the inside of the EBR line towards the wafer center. EBR area 16 is external to the EBR line. Imaging area 62 extends in the area of edge area 13 starting from the wafer edge 12 in the form of a line across EBR area 16 towards the wafer center across EBR line 15 and beyond into the area of photoresist layer 14. Illumination beam 61 has its center at about the area of the EBR line in the imaging area in the top view as a tangent to the EBR line. Imaging beam 63 is also reflected tangentially from the EBR line. Wafer 10 is rotated by the rotary means beneath imaging area 62. This is how imaging area 62 scans edge area 13 of the wafer in the form of lines and shows it as an annular surface via image processing means 70.

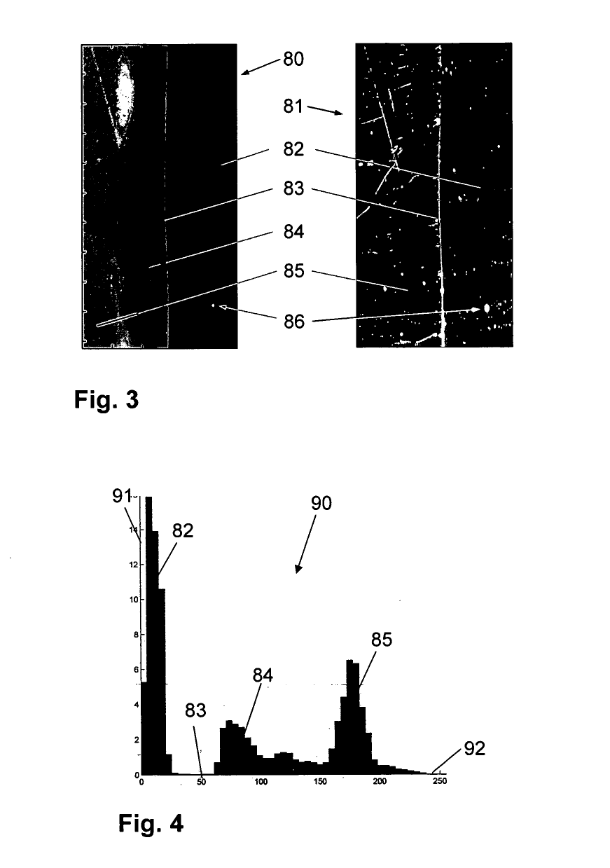

FIG. 3 shows a partial view 80 of a fluorescence image and a partial view 81 of a dark-field image based upon scattered light. The two images are taken from an identical partial area on edge area 13 of a wafer. The areas 82 show the edge bead removal area 16 of the wafer. The line or area boundary 83 shows EBR line 15. Area 84 shown darker in the fluorescence image shows a first photoresist area, areas 85 show a second photoresist area. In the dark-field image, various additional defects can be seen, such as defect 86, that can also be detected in the fluorescence image. This may well be a stray drop of photoresist. Two photoresist areas can be recognized in fluorescence images 84 and 85, with a brightness contrast in the black and white image shown here, which can be recognized as an image contrast in the color image in a more differentiated way.

FIG. 4 shows a brightness histogram of fluorescence image 80. Axis 92 shows the brightness values of the image, and axis 91 shows the frequency of the brightness values in the image. Areas 82 with the photoresist removed can be seen in the area of the dark values on the left. No photoresist is present there, which could generate fluorescent light, which is why this area remains dark in the image. There is a smallish peak 84 in the mean values representing the first photoresist area. In fluorescence image 80 it can be seen as dark gray. Towards the brighter values, there is another peak 85 corresponding to the second photoresist area of image 80. In fluorescence image 80 it is shown as light gray. Between peak 82 of the area without photoresist and peak 84 of the first photoresist area, a minimum 83 is noticeable. The position of this minimum 83 on the brightness axis 92 marks the threshold value for identifying the EBR line in the fluorescence image. Brightness values with smaller brightness than the threshold value are defined as lying within the EBR area, brightness values with higher brightness than the threshold value are defined as lying within the photoresist area. In this way it is possible to separate the two areas in the image by means of computation and automatically to obtain the EBR line as the separating line between the two areas computationally.

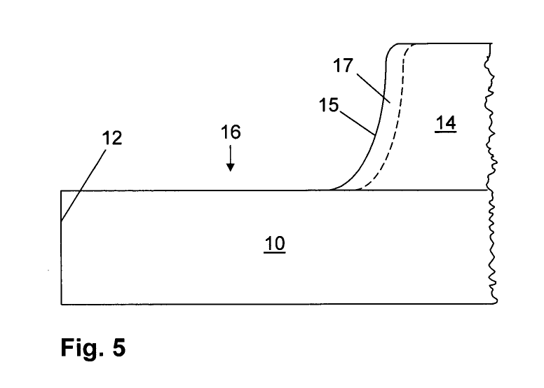

FIG. 5 shows a cross-section of the wafer in the area of the EBR line, wherein the wafer has had the edge bead removed according to the method of the present invention. The edge bead removal is usually carried out in a wet centrifugal method in which an EBR liquid is sprayed onto the surface of the rotating wafer in the area of its edge. This dissolves the photoresist, is carried off towards the outside due to centrifugal forces, and rinses the thus dissolved photoresist off the surface of the wafer. In the process, an EBR line 15 is formed, as shown in the figure. EBR liquid penetrates in the photoresist and softens it so it can be rinsed off. In a diffusion area 17, the EBR liquid also penetrates in the remaining EBR line 15. As a result of using a fluorescent EBR liquid, diffusion area 17 shows fluorescence. In a fluorescence image taken from above, EBR line 50 can therefore be readily recognized in the image due to its fluorescent diffusion area 17.

What is clamed is:

1. A method of optically imaging a wafer with a photoresist layer, comprising the steps of:
a) illuminating an imaging area on the surface of the wafer with light of a wavelength range between 360 nm and 500 nm, wherein the light is polychrome; and,
b) imaging a fluorescence image of the imaging area from the fluorescent light radiated due to the illumination by the excitation light and wherein the fluorescence image is a color image.

2. The method according to claim 1, wherein the fluorescence image is taken in the dark field.

3. The method according to claim 1, wherein in addition to the fluorescence image, a dark-field image is taken of the imaging area from the scattered light of the illuminated imaging area.

4. The method according to claim 3, wherein the fluorescence image and the dark-field image are taken simultaneously.

5. The method according to claim 3, wherein the fluorescence image and the dark-field image are taken by the same camera coextensively.

6. The method according to claim 3, wherein the fluorescence image is taken by a color camera and the dark-field image is taken by a monochromatic camera.

7. The method according to claim 6, wherein the monochromatic camera has a higher resolution than the color camera.

8. The method according to claim 6, wherein the one or two cameras are one or two linear array cameras and in that the imaging area has a linear extension and is moved relative to the wafer surface during imaging in a direction perpendicular to its extension.

9. The method according to claim 8, wherein the imaging area is oriented in a radial direction toward the center of the wafer and in that the wafer is rotated about its center axis for movement.

10. The method according to claim 9, wherein the imaging area scans a circular annulus on the wafer delimited by the edge of the wafer.

11. The method according to claim 10, wherein the imaging area covers the EBR line of the wafer.

12. The method according to claim 1, wherein after imaging an evaluation of the fluorescence image is carried out and a location of the EBR line is identified.

13. The method according to claim 12, wherein after imaging an evaluation of the fluorescence image is carried out and the areas are classified in the image.

14. The method according to claim 1, wherein in that after imaging the fluorescence image is evaluated by:
a) creating a histogram of the image or images;
b) finding a threshold value from the histogram:
c) comparing the image with the threshold value; and
d) classifying areas in the image on the basis of the comparison.

15. The method according to claim 14, wherein the classified areas correspond to areas on the wafer separated by an EBR line.

16. The method according to claim 3, wherein the fluorescence image is compared to the dark-field image.

17. A photoresist for the manufacture of semiconductor elements on wafers, comprises a fluorescent dye added to the photoresist.

18. A method of edge bead removal and of inspecting a wafer, comprises the steps of:
a) partially removing the photoresist from the wafer with a fluorescent EBR liquid, wherein fluorescent EBR liquid diffuses into the EBR line towards the area where the photoresist remains;
b) illuminating an imaging area on the surface of the wafer with light of a wavelength range between 360 nm and 500 nm, wherein the light is polychrome;
c) imaging a fluorescence image of the imaging area from the fluorescent light radiated due to the illumination by the excitation light and wherein the fluorescence image is a color image; and,
d) evaluating the fluorescence image by identifying the fluorescent EBR line.

19. An edge bead removal liquid for at least partially removing the photoresist from a wafer, wherein the edge bead removal liquid consists of a solvent and an additional fluorescent dye.
